(19) United States
(12) Patent Application Publication
(10) Pub. No.: US 2010/0187005 A1
(43) Pub. Date: Jul. 29, 2010

(54) Flat cable fixing structure

(76) Inventor: Shih-Kun Yeh, Taoyuan Hsieh (TW)

Correspondence Address: Jackson Intellectual Property Group PLLC, 106 Starvale Lane, Shipman, VA, 22971, US

(21) Appl. No.: 12/010,224

(22) Filed: Jan. 22, 2008

(51) Int. Cl. H05K 1/00

(52) U.S. Cl. 174/268

(57) ABSTRACT

The present invention provides a flat cable fixing structure that includes a flexible flat cable (FFC) and a positioning element. The flexible flat cable is connected to a printed circuit board, and the positioning element is provided for fixing the flexible flat cable to the printed circuit board to achieve the effect of securely fixing the flexible flat cable onto the printed circuit board. When the flat cable fixing structure is applied to various types of electronic products, the invention can overcome the shortcomings of the prior art that the flat cable and the printed circuit board may be separately from each other easily by an external force, and the difficulty of aligning soldering points.

### BACKGROUND OF THE INVENTION

1. Field of the Invention

The present invention relates to a flat cable fixing structure that provides a means for fixing a flat cable securely with a circuit board.

2. Description of the Related Art

Flexible printed circuit (FPC) board is a printed circuit board having etched circuits, jump wires, component soldering points and cuttable and flexible circuit boards. Since FPC can greatly reduce the space occupied by the printed circuit board, the FPC is used extensively in various types of electronic products, particularly to compact portable electronic products such as notebook computers, mobile phones, digital cameras, VCD/DVD drives and automobile displays. In most applications of the flexible printed circuit board, a connector is adopted for connecting different circuits and devices such as the connection between a display panel and a signal control circuit, for transmitting video signals to the display panel and controlling the screen display on the display panel.

Referring to FIG. 1A for a schematic view of connecting a prior art flexible printed circuit board with a printed circuit board, the printed circuit board 90 includes a plurality of contact points 91, and the flexible printed circuit board 70 has a circuit, a contact point 71 and a fixing hole 72, such that when the flexible printed circuit board 70 is soldered with a contact point 91 of the printed circuit board 90 through a contact point 71 to achieve the electric conduction effect, and the fixing hole 72 is soldered onto the printed circuit board 90, so that the flexible printed circuit board 70 and the printed circuit board 90 can be fixed with each other more securely to prevent the flexible printed circuit board 70 from being separated by an external force.

However, the flexible printed circuit board (FPCB) still has the drawbacks of the incapable of having a bent acute angle and a high price, and thus the flat cable (FFC) can lower the cost by replacing the FPCB by FFC. Referring to FIG. 1(B) for a schematic view of connecting a flat cable with a printed circuit board, the printed circuit board 90 includes a plurality of contact points 91, and the front end of the flat cable 80 further includes a plurality of cores 81 installed corresponding to the contact points 91, and the cores 81 are fixed to the contact points 91 by a soldering method to achieve the electric conduction effect. If the core 81 and the contact point 91 are soldered, and the flat cable 80 or the printed circuit board 90 is collided by an external force by accident, the corresponding relation between the cores 81 and the contact points 91 will be deviated, such that before the soldering operation takes place, it is necessary to arrange the cores 81 neatly to align the core 81 with each corresponding contact point 91 precisely. However, this operation extends the soldering operation time, and thus increases the production cost, which is incompliant with the cost-effectiveness. In addition, the flat cable 80 and the printed circuit board 90 are fixed by the soldering of the core 81 and the contact point 91, and thus if an external force is applied accidentally to pull the flat cable 80 or the printed circuit board 90, the core 81 may be cracked or broken, so that a broken circuit will occur between the flat cable 80 and the printed circuit board 90, and the product will not be used anymore.

### SUMMARY OF THE INVENTION

In view of the shortcomings of the prior art, the inventor of the present invention based on years of experience in the related industry to conduct extensive researches and experiments, and finally developed a flat cable fixing structure in accordance with the present invention to overcome the shortcomings of the prior art.

Therefore, it is a primary objective of the present invention to provide a flat cable fixing structure comprising a flexible flat cable (FFC) and a positioning element, wherein the flexible flat cable is connected to a printed circuit board, and the positioning element is provided for fixing the flexible flat cable to the printed circuit board to achieve the effect of securely fixing the flexible flat cable to the printed circuit board. If the flexible flat cable is applied to various types of electronic products, the invention can overcome the shortcomings of the prior art that the flat cable and the printed circuit board may be separated from each other by an external force, and the difficult of aligning the soldering points.

### BRIEF DESCRIPTION OF THE DRAWINGS

FIG. 1(A) shows a schematic view of fixing a prior art flexible printed circuit board with a printed circuit board;

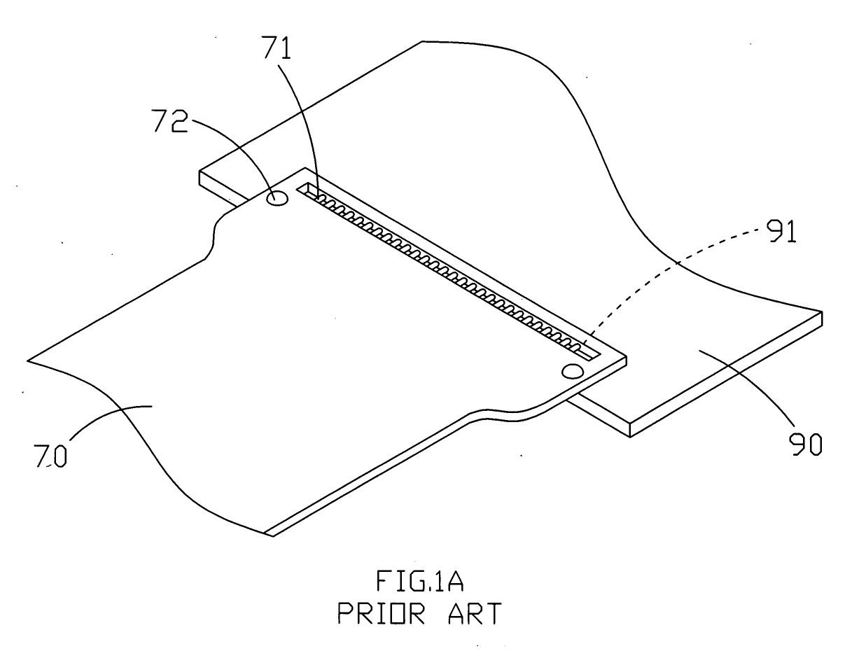

FIG. 1(B) shows a schematic view of fixing a prior art flat cable with a printed circuit board;

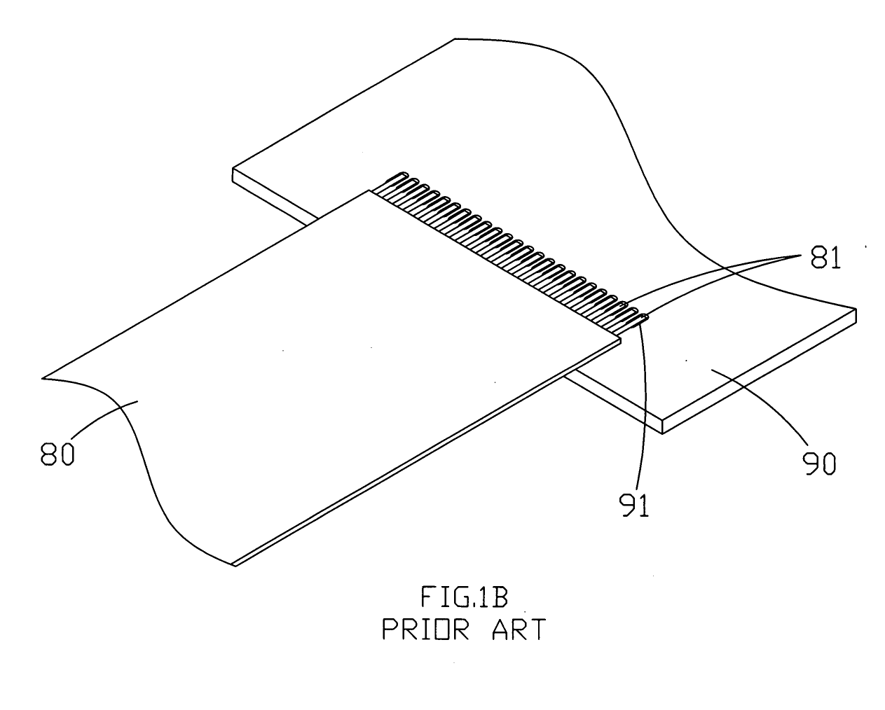

FIG. 2 shows a schematic view of a flat cable fixing structure in accordance with a first preferred embodiment of the present invention;

FIG. 3 shows an exploded view of a flat cable fixing structure in accordance with a first preferred embodiment of the present invention;

FIG. 4 shows a schematic view of a flat cable fixing structure in accordance with a second preferred embodiment of the present invention;

FIG. 5 shows a schematic view of a flat cable fixing structure in accordance with a third preferred embodiment of the present invention;

FIG. 6 shows a schematic view of a flat cable fixing structure in accordance with a fourth preferred embodiment of the present invention; and

FIG. 7 shows a schematic view of a flat cable fixing structure in accordance with a fifth preferred embodiment of the present invention.

### DETAILED DESCRIPTION OF THE PREFERRED EMBODIMENTS

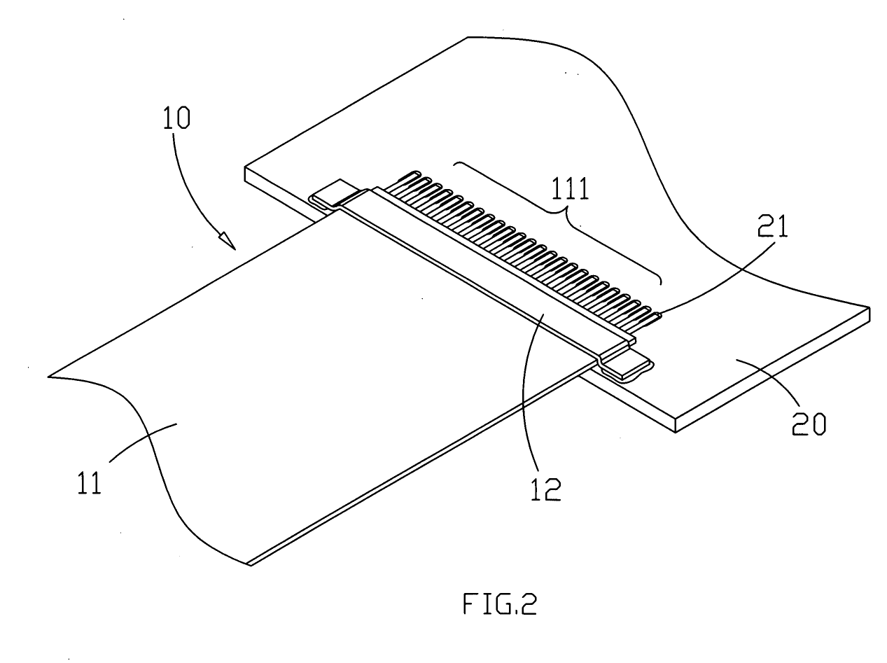

Referring to FIG. 2 for a flat cable fixing structure in accordance with the present invention, the flat cable fixing structure 10 comprises a flexible flat cable (FFC) 11 and a positioning element 12, and the flexible flat cable 11 is connected to a printed circuit board 20 and fixed onto the printed circuit board 20 by the positioning element 12, so that the flexible flat cable 11 cannot be separated from the printed circuit board 20 in order to achieve the effect of securely fixing and positioning the flexible flat cable 11 onto the printed circuit board 20. The way for the positioning element 12 to fix the flexible flat cable 11 to the printed circuit board 20 will be described as follows.

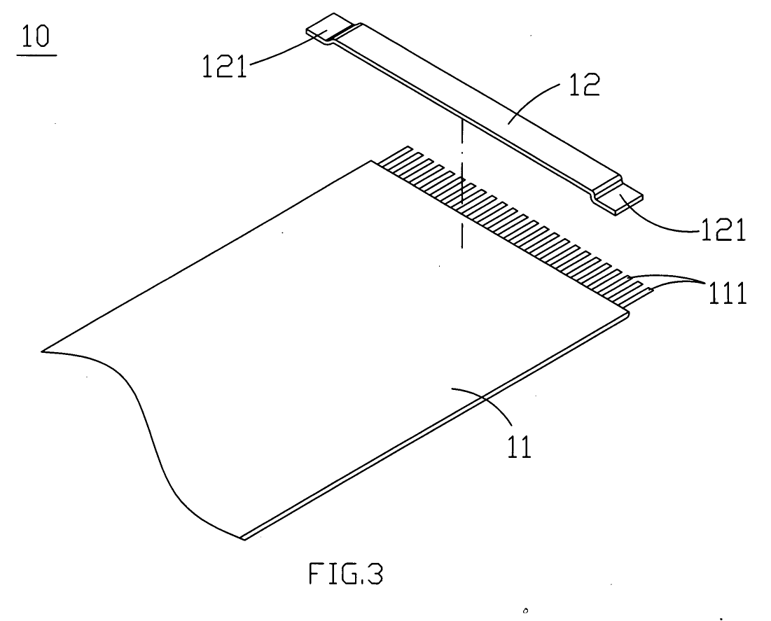

In an application, the positioning element 12 is in the form of a press board made of a rigid board, and the length of the positioning element 12 is greater than the width of the flexible flat cable 11 in this embodiment, such that when the positioning element 12 is pressed and engaged with the flexible flat cable 11 (such as an end of the flexible flat cable 11, both ends of the positioning element 12 will be exposed from the flexible flat cable 11 and connected to the printed circuit board 20. With the pressing and engagement of the positioning element 12, the flexible flat cable 11 is limited in the positioning element 12 and prevented from its falling out. As a result, the flexible flat cable 11 is fixed onto the printed circuit board. In FIG. 3, both ends of the positioning element 12 separately have a cascade portion 121, and the height of the cascade portion 121 is substantially equal to the thickness of the flexible flat cable 11, and the middle section of the positioning element disposed between the cascade portions on both sides can be attached onto the flexible flat cable 11 for adhering the positioning element 12 and the flexible flat cable 11, and then both ends of the positioning element 12 are used for connecting the positioning element 12 to the printed circuit board 20, so that the positioning element 12 is fixed with the flexible flat cable 11, and the positioning element 12 is fixed with the printed circuit board 20, and the flexible flat cable 11 and the positioning element 12 and the printed circuit board 20 form a secured fixing structure to prevent the flexible flat cable 11 from being separated from the printed circuit board 20.

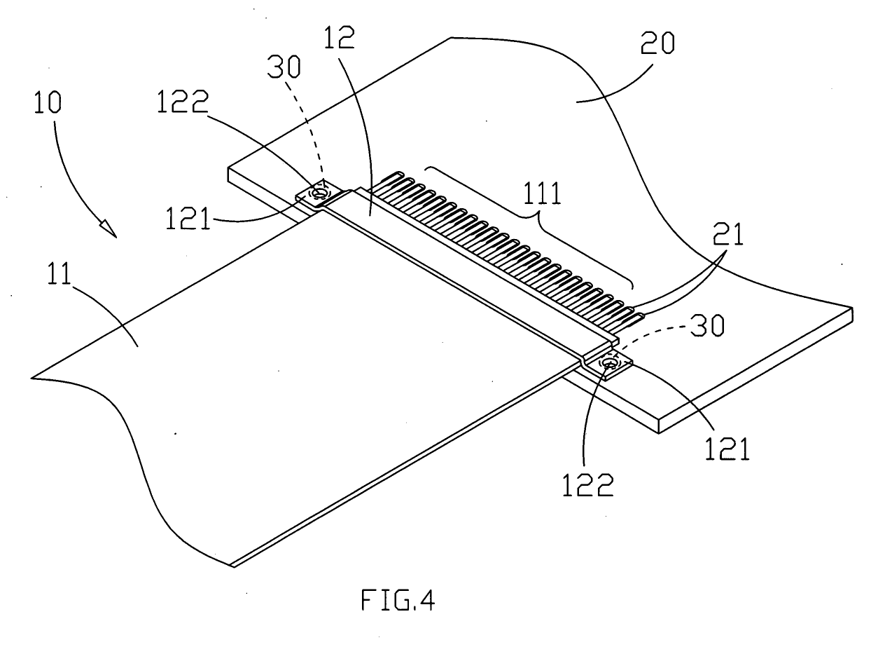

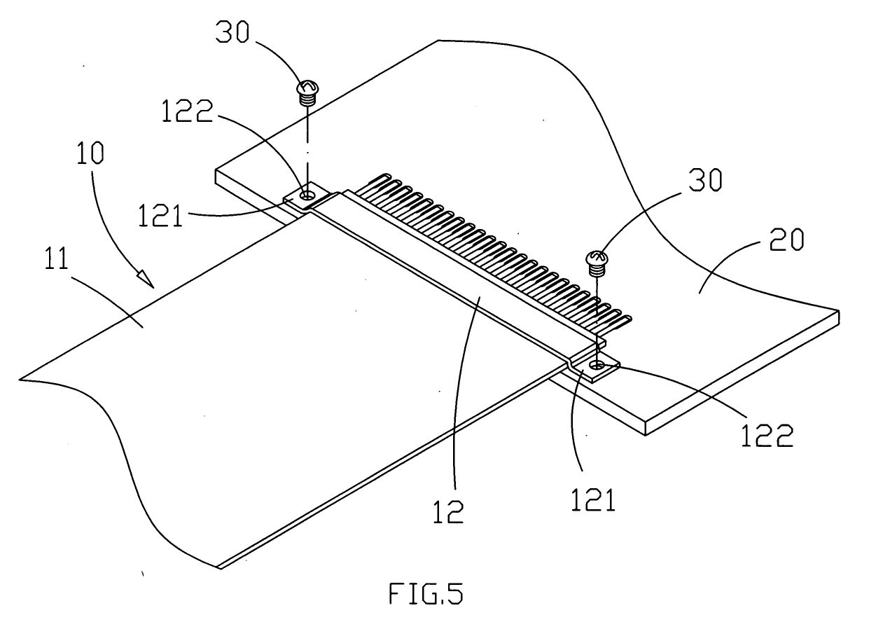

Referring to FIG. 4 for a flat cable fixing structure in accordance with a second preferred embodiment of the present invention, both ends of the positioning element 12 separately have a hole 122 for passing and fixing the fixing element 30 to the printed circuit board 20, and the fixing element 30 in this embodiment is a solder. With the hole 122, the fixed area of the solder can be increased to securely soldering the positioning element 12 onto the printed circuit board 20. Referring to FIG. 5 for a flat cable fixing structure in accordance with a third preferred embodiment of the present invention, the fixing element 30 is a screw secured into the hole 122 and locked onto the printed circuit board 20, so that the positioning element 12 can be secured onto the printed circuit board 20 to achieve the fixing effect.

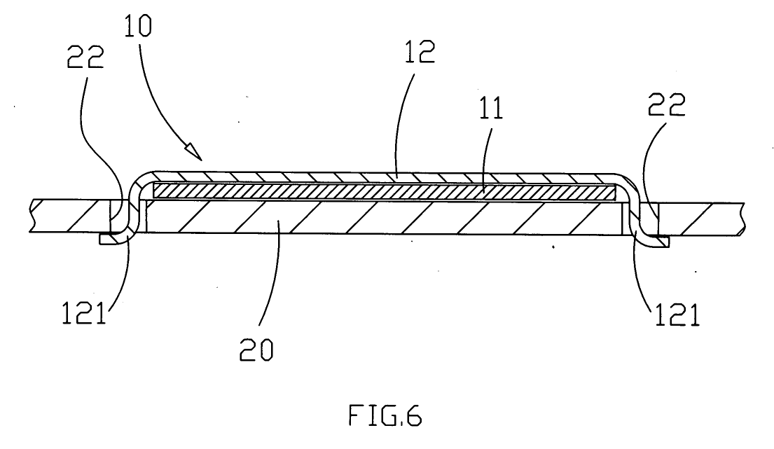

Referring to FIG. 6 for a flat cable fixing structure in accordance with a fourth preferred embodiment of the present invention, the positioning element 12 is fixed onto the flexible flat cable 11. By inserting the cascade portions 121 exposed from both ends of the flexible flat cable 11 into the preset positioning through holes 22 on the printed circuit board 20, we can achieve the fixing function.

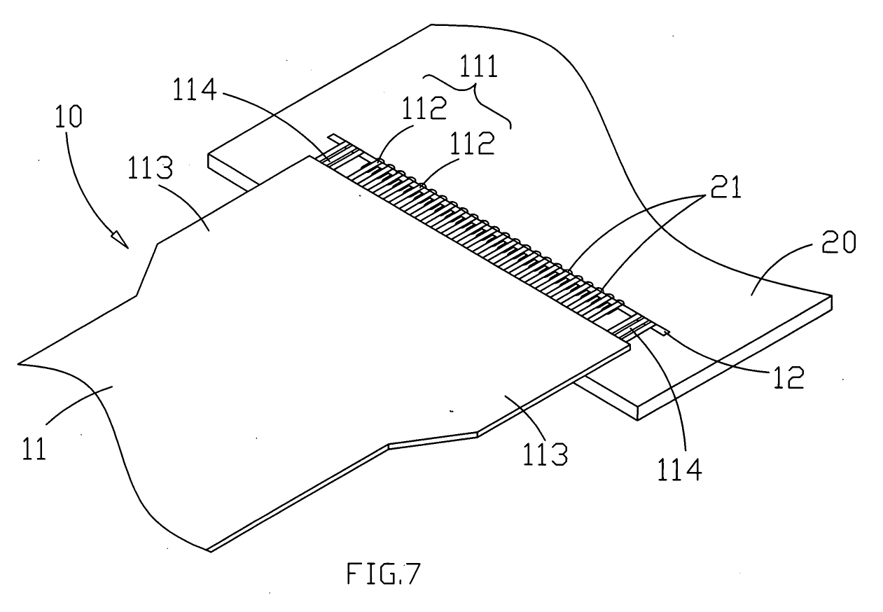

Referring to FIG. 7 for a flat cable fixing structure in accordance with a fifth preferred embodiment of the present invention, the front end of the flexible flat cable 11 includes a core module 111 fixed onto the printed circuit board 20 to electrically connect the flexible flat cable 11 with the printed circuit board 20. In this embodiment, the positioning element 12 is installed on the core module 111 and fixed onto the printed circuit board 20, so that the cores 112 on the core module 111 are maintained with a predetermined interval apart. In other words, each core 112 will not be tilted, so that each core 112 can be aligned precisely with a corresponding soldering point 21 on the printed circuit board 20. Both sides of the front end of the flexible flat cable 11 separately form a wing portion 113, and both ends of the core module 111 separately have a reinforced wire module 114 installed corresponding to the wing portion 113. With the reinforced wire modules 114 on both sides, the fixing strength between the core module 111 and the positioning element 12 can be enhanced.

It is noteworthy to point out that the present invention adopts a flat cable fixing structure to combine and electrically connect the flexible flat cable with the printed circuit board, and the flat cable fixing structure can be used in various types of electronic devices and products such as a notebook computer. The invention can overcome the drawbacks of the prior art that the flat cable and the printed circuit board may be separated easily from each other at the connecting position by an external force.

In summation of the description above, the present invention improves over the conventional structure, and complies with the requirements of patent application, and is thus duly filed for patent application.

While the invention has been described by means of specific embodiments, numerous modifications and variations could be made thereto by those skilled in the art without departing from the scope and spirit of the invention set forth in the claims.

What is claimed is:

1. A flat cable fixing structure, comprising: a flexible flat cable (FFC) and a positioning element, wherein the positioning element is installed on the flexible flat cable, and the flexible flat cable is coupled to the printed circuit board.

2. The flat cable fixing structure of claim 1, wherein the positioning element is a press board, whose length is greater than the width of the flexible flat cable, such that when the positioning element is pressed and engaged to an end of the flexible flat cable, both ends of the positioning element are exposed from the flexible flat cable, and coupled to the printed circuit board.

3. The flat cable fixing structure of claim 2, wherein the positioning element has a cascade portion disposed separately on both ends of the positioning element, and the height of the cascade portion is substantially equal to the thickness of the flexible flat cable.

4. The flat cable fixing structure of claim 2, wherein the middle section of the positioning element is adhered to the flexible flat cable.

5. The flat cable fixing structure of claim 2, wherein both ends of the positioning element are fixed to the printed circuit board by a soldering method.

6. The flat cable fixing structure of claim 2, wherein the positioning element has a hole disposed separately on both ends of the positioning element, for passing and fixing the fixing element to the printed circuit board.

7. The flat cable fixing structure of claim 6, wherein the fixing element is a screw or a solder.

8. The flat cable fixing structure of claim 2, wherein the positioning element is inserted into a preset positioning through hole on the printed circuit board through the cascade portion to achieve a positioning function.

9. A flat cable fixing structure, comprising a flexible flat cable (FFC) and a positioning element, wherein the positioning element is disposed on an end of the flexible flat cable and proximate to the printed circuit board, and the flexible flat cable is coupled to the printed circuit board, and the flexible flat cable is fixed onto the printed circuit board by the positioning element to achieve the effect of securely fixing the flexible flat cable to the printed circuit board.

10. The flat cable fixing structure of claim 9, wherein the positioning element is a press board, whose length is greater than the width of the flexible flat cable, such that when the positioning element is pressed and engaged to an end of the flexible flat cable, both ends of the positioning element are exposed from the flexible flat cable, and coupled to the printed circuit board.

11. The flat cable fixing structure of claim 9, wherein the positioning element has a cascade portion disposed separately on both ends of the positioning element, and the height of the cascade portion is substantially equal to the thickness of the flexible flat cable.

12. The flat cable fixing structure of claim 9, wherein the middle section of the positioning element is adhered to the flexible flat cable.

13. The flat cable fixing structure of claim 9, wherein both ends of the positioning element are fixed to the printed circuit board by a soldering method.

14. The flat cable fixing structure of claim 9, wherein the positioning element has a hole disposed separately on both ends of the positioning element, for passing and fixing the fixing element to the printed circuit board.

15. The flat cable fixing structure of claim 14, wherein the fixing element is a screw or a solder.

16. The flat cable fixing structure of claim 9, wherein the positioning element is inserted into a preset positioning through hole on the printed circuit board through the cascade portion to achieve a positioning function.

17. A flat cable fixing structure, comprising: a flexible flat cable (FFC) and positioning element, wherein the flexible flat cable includes a core module disposed at a front end of the flexible flat cable, and fixed to the printed circuit board to constitute an electric conduction, and the positioning element is disposed on the core module and fixed onto the printed circuit board, such that the cores on the core module are maintained in a predetermined interval to prevent each core from being tilted.

18. The flat cable fixing structure of claim 17, wherein the flexible flat cable includes a wing portion disposed separately on both lateral sides of the front end of the flexible flat cable, and the core module includes a reinforced wire module disposed separately on both sides of the core module, and corresponding to the wing portions respectively.
